(19) United States
(12) Patent Application Publication
(10) Pub. No.: US 2006/0006391 A1
(43) Pub. Date: Jan. 12, 2006

(54) Image display devices

(76) Inventors: Mieko Matsumura, Kokubunji (JP); Mutsuko Hatano, Kokubunji (JP); Toshihiko Itoga, Chiba (JP); Eiji Oue, Mobara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/171,184

(22) Filed: Jul. 1, 2005

(30) Foreign Application Priority Data
Jul. 5, 2004 (JP) 2004-197750

(51) Int. Cl. H01L 29/04; H01L 29/15; H01L 21/84

(52) U.S. Cl. 257/72; 257/59; 438/149; 438/157; 257/351

(57) ABSTRACT

To obtain a system-in-display with high performance and multifunction at low cost, high performance and reliability of a low temperature polysilicon thin film transistor is devised by terminating traps at a interface between a gate oxide film and a polycrystalline silicon film constituting a channel with fluorine. To maximize its effect, a material not governed by scattering due to potential barriers at grain boundaries, that is, a crystalline thin film approximately in a band shape having fewer grain boundaries that segmentalize the channel is used for the channel portion of the transistor. In this way, it is possible to realize the thin film transistor having both steep transfer characteristic and excellent resistance to hot carriers to unite high performance and reliability, construct various circuits that operate at low power and high speed on the same glass substrate as for pixel portions, and obtain the system-in-display having high performance and multifunction at low cost.

### CLAIM OF PRIORITY

The present application claims priority from Japanese application JP 2004-197750 filed on Jul. 5, 2004, the content of which is hereby incorporated by reference into this application.

### FIELD OF THE INVENTION

The present invention relates to an image display device, and more particularly to an image display device such as a liquid crystal display and an organic EL display provided with field effect transistors suitably modified to be mounted on an active matrix substrate used as a driving circuit.

### BACKGROUND OF THE INVENTION

An image display device provided with an active matrix substrate that has a pixel area with numerous pixels formed in a matrix and a peripheral circuit area formed around the periphery of the pixel area as an active circuit to send signals to the pixels is widely used in the field of various image display devices.

Part of the peripheral circuits for a flat panel display of medium or small size such as a portable telephone is assembled on the same substrate as for pixels, while most of it is constructed with the use of external LSI chips.

A thin film transistor that is currently used for mass goods as a semiconductor device constituting the main part of the pixels and peripheral circuits is mainly made of polycrystalline silicon that is obtained by crystallization of amorphous silicon thin film by means of excimer laser annealing (hereinafter, referred to as ELA crystal). In addition, crystalline silicon by solid phase growth that is obtained by thermal annealing of amorphous silicon thin film in an electric furnace, polycrystalline silicon formed directly by thermal chemical vapor deposition and catalytic chemical vapor deposition, and the like are also used.

It is desirable that a display device is made thinner and its frame is made narrower in view of weight reduction of a portable good and its free designing. One of the methods to achieve the above is incorporation of the peripheral circuits onto a glass substrate. The incorporation of the peripheral circuits onto the glass substrate makes it possible to reduce the number of external LSI chips and their mounting processes, thereby allowing a display device to be manufactured at a lower cost.

In order to realize incorporation of more peripheral circuits onto a glass substrate and an image display device having a larger number of pixels, a circuit that operates at higher driving frequencies is required. To increase driving frequencies of a circuit, an increase of power voltage or an enhancement of performance of a thin film transistor is required.

However, since portable instruments use battery as the power source, the increase of power voltage that leads to an increase of power consumption is not desirable. Therefore, it is necessary to fabricate a high performance thin film transistor that operates at a high speed and at a lower voltage on the same glass substrate as for the pixel area.

The development of a high performance thin film transistor that operates at a high speed and at a lower voltage has been widely conducted to date. As a method to obtain a transistor with high performance and high reliability that is not limited to a thin film transistor, there is a method in which trap levels present at the interface between a gate oxide film and a semiconductor film are terminated with mono-valent atoms such as hydrogen and fluorine.

An atom used for the termination is preferred to be as small as possible from a standpoint that peripheral atomic arrangement is not disturbed and that diffusion is easy. Accordingly, termination of the trap levels with the use of hydrogen is popular at present.

However, an bond between hydrogen and silicon atoms is cleaved upon collision with carriers that have come to have an energy higher than a thermal temperature produced by a high electric field in a channel (hereinafter, referred to as hot carrier), thereby loosing its termination effect. As a result, characteristics of the thin film transistor deteriorate, and display characteristics of an image display device deteriorate. In view of endurance of the termination effect, it is desirable to have a stronger bond to silicon atom. Accordingly, fluorine that is not too large and forms a strong bond to silicon is suitable for the atomused for the termination. As for documents related to this technology, Patent Document 1 [Japanese Patent No. 2846329 (Japanese Patent Laid-Open No. H2(1990)-205016)] is listed.

A method to enhance the performance of a thin film transistor by introducing fluorine into it is described in Patent Documents 2 (Japanese Patent Laid-Open No. H5(1993)-152333) and 3 (Japanese Patent Laid-Open No. H11(1999)-330474), in both of which fluorine is introduced into thin film transistors using granular crystals obtained by ELA. For this reason, substantial enhancement in performance and reliability could not be attained, and therefore it was difficult to install a circuit driven at a low voltage.

The present inventors have previously proposed in Patent Document 4 (Japanese Patent Laid-Open No. 2002-222959) that a crystalline thin film approximately in a band shape is applied to a channel for a thin film transistor constituting a driving circuit in order to drive pixels of an image display device at a high speed. In the subsequent research and development, they realized that realization of a thin film transistor that satisfies both of further steep transfer characteristic and excellent resistance to hot carriers for the thin film transistor constituting the driving circuit was an urgent matter.

The object of the present invention is to obtain a thin film transistor with excellent characteristics and reliability that is suitable for driving pixels on the same active matrix substrate as for a pixel area in order to realize a high performance image display device having a large number of pixels at a low cost.

That is, the object of the present invention is to realize a thin film transistor having both steep transfer characteristic and excellent resistance to hot carriers and further both high performance and high reliability that is suitable for driving pixels and to form various circuits that operate at a low electric power and at a high speed on the same active matrix substrate as for the pixel area in order to obtain a system-in-display having high performance and multifunction at a low cost.

### SUMMARY OF THE INVENTION

A feature of the present invention to achieve the above object is that, for a thin film transistor suitable to form a driving circuit for driving pixels, fluorine is introduced into the interface between a gate oxide film and a semiconductor thin film forming a channel, interface trap levels are terminated by the fluorine, and the semiconductor thin film makes use of a crystalline semiconductor thin film approximately in a band shape to take advantage of the effect of enhancement in performance of the thin film transistor due to the interface termination.

In other words, the driving circuit of the image display device makes use of a thin film transistor in which the concentration of fluorine at the interface between the gate oxide film and the semiconductor thin film forming the channel is higher than that in the inside of the semiconductor thin film and the semiconductor thin film is a crystalline thin film approximately in a band shape in which crystal grains are allowed to grow and crystallize in the direction nearly parallel to the direction of current conduction.

Construction of the semiconductor thin film forming the channel approximately in a band shape is characterized in that the main alignment with respect to the surface of the semiconductor thin film is {110} as proposed previously in Patent Document 4 by the present inventors (Japanese Patent Laid-Open No. 2002-222959).

Further, an outline of the present invention will be specifically explained below by exemplifying an n-channel thin film transistor with reference to the accompanying drawings and in comparison with a conventional technology. FIG. 1 and FIG. 2 represent schematic diagrams of crystal shapes viewed from the upper side and the cross section of the channel region of the thin film transistor and potential distribution for electrons assuming an ON state of the n-channel thin film transistor.

FIG. 1(1) is a plan view showing crystal shapes when a thin film transistor making use of conventional ELA crystals for a channel region is viewed from above. FIG. 1(2) and FIG. 1(4) are cross sectional views showing schematically the crystal shapes of the cross sections along the lines A-A′ and A″-A′″ in FIG. 1(1), respectively. FIG. 1(3) and FIG. 1(5) are schematic diagrams showing potential distributions for electrons corresponding to the line B-B′ in FIG. 1(2) and the line B″-B′″ in FIG. 1(4), respectively. In these figures, all gate oxide films are omitted, and in FIG. 1(1), a gate electrode GT is also omitted. NSD indicates the source and drain regions.

The ELA crystals are granular crystals having a number of columnar grain boundaries GB in the thickness direction of the film as shown in FIG. 1(2) and formed with the grain boundaries GB in a mesh pattern in which granular crystals are filled when viewed from above as shown in FIG. 1(1). In the crystal grain boundaries GB, trap levels GBT are present, and also at the interface between the gate oxide film and the crystalline thin film, interface trap levels IT are present.

When a positive voltage is applied to the gate electrode GT to open the channel in the n-channel thin film transistor, the Fermi level EF rises, and the trap levels of the grain boundaries and the interface are occupied by electrons. Particularly, the negatively charged trap levels at the grain boundaries GBT form potential barrier against electrons as shown by EC (lower end of conduction band) in FIG. 1(3) and FIG. 1(5), and conduction of electrons is inhibited. Note that EV in these figures indicates the upper end of valence band.

Since current conduction of a thin film transistor making use of ELA crystal is mainly governed by scattering due to the potential barrier of the grain boundaries crossing the channel, terminating the trap levels IT at the interface between the gate oxide film and the ELA crystal with fluorine atom provides little effect on the characteristics of the thin film transistor.

Next, a thin film transistor in which the channel is formed with a semiconductor thin film consisted of crystals approximately in a band shape according to Patent Document 4 (Japanese Patent Laid-Open No. 2002-222959) proposed previously by the present inventors and the interface termination is performed with fluorine will be explained according to FIG. 2. The contents in FIG. 2 are similar to those in FIG. 1 shown above. FIG. 2 (1) is a plan view showing crystal shapes when a thin film transistor that uses crystals approximately in a band shape for the channel region so that the growth direction of the crystal may become parallel to the direction of current conduction is viewed from above. FIG. 2(2) and FIG. 2(4) are cross sectional views showing schematically the crystal shapes of the cross sections along the lines A-A′ and A″-A′″ in FIG. 2 (1), respectively. FIG. 2(3) and FIG. 2(5) are schematic diagrams showing potential distributions for electrons corresponding to the line B-B′ in FIG. 2(2) and the line B″-B′″ in FIG. 2(4), respectively.

In the thin film transistor that uses the crystals approximately in a band shape so that the growth direction of the crystal may become nearly parallel to the channel direction, the number of the grain boundaries GB crossing the channel is reduced as shown by the line A-A′ in FIG. 2(1) and in FIG. 2(2), and further, there are regions where a straight line can be drawn from the source region (NSD) to the drain region (NSD) without crossing any grain boundary.

Even in the crystals approximately in a band shape, potential barriers are formed due to trap levels GBT present in the grain boundaries GB. However, current conduction of the thin film transistor becomes not to be governed only by scattering caused by the potential barriers of the grain boundaries for two reasons that the number of the grain boundaries crossing the channel is small as described above and there are regions where carriers can move from the source region to the drain region without crossing potential barriers of the grain boundaries.

What influences the characteristics of the thin film transistor besides scattering caused by the potential barriers of the grain boundaries is weakening of the relation between gate voltage and surface potential by the interface trap levels IT. When there exist many interface trap levels IT, an application of a positive voltage to the gate electrode GT to open the channel raises the Fermi level EF at the interface and the trap levels at the interface are occupied by electrons, thereby inhibiting channel formation. The interface levels are energetically distributed, and the higher the Fermi level of the interface is raised, the more levels become lower than the Fermi level. Therefore, the number of electrons that are captured by the interface trap levels increases. As a result, the larger the number of the interface trap levels becomes, the weaker the relation between the gate voltage and the surface potential becomes, resulting in deterioration of the transfer characteristics of the thin film transistor.

When the interface trap levels of the thin film semiconductor making use of the crystals approximately in a band shape are terminated by fluorine according to the present invention, the influence of scattering due to the potential barriers of the grain boundaries is weakened, and therefore a greater effect on transistor characteristics can be acquired compared to a case where the interface trap levels of a thin film semiconductor making use of granular crystals are terminated.

It is desirable that not only is the interface level density at the interface between the gate oxide film and the semiconductor thin film that constitute the above thin film transistor equal to or lower than 7×1101/cm²/eV at the mid of the band-gap but also the above semiconductor thin film is a crystalline thin film approximately in a band shape in which crystal grains are allowed to grow and crystallize in the direction nearly parallel to the direction of current conduction.

In particular, characteristics of the rising edge in the subthreshold region become steep and excellent, and it is possible to obtain a transistor having a high driving capability even at a low voltage. At the same time, resistance to hot carriers is improved, and a transistor with high reliability can be obtained.

Further, it is desirable that the atomic concentration of fluorine relative to silicon at the interface is equal to or higher than 0.05%.

In the foregoing, the effect of the present invention on n-channel thin film transistor is described. A similar effect is also achieved on p-channel thin film transistor.

According to the present invention, it is possible to realize a thin film transistor having both steep transfer characteristic and excellent resistance to hot carriers, to form various circuits on the same active matrix substrate as for the pixel area, and to obtain a system-in-display having high performance and multifunction at a low cost.

### BRIEF DESCRIPTION OF THE DRAWINGS

FIG. 1 is a schematic diagram of a thin film transistor making use of conventional ELA crystals for its channel region, where FIG. 1(1) is a plan view of crystal shapes, FIG. 1(2) is a cross sectional view of the crystal shapes, FIG. 1(3) is a schematic representation of potential distribution for electrons, FIG. 1(4) is another cross sectional view of the crystal shapes, and FIG. 1(5) is another schematic representation of the potential distribution for electrons;

FIG. 2 is a schematic diagram of a thin film transistor making use of crystals approximately in a band shape for its channel region, where FIG. 2 (1) is a plan view of the crystal shapes, FIG. 2(2) is a cross-sectional view of the crystal shapes, FIG. 2(3) is a schematic representation of the potential distribution for electrons, FIG. 2(4) is another cross sectional view of the crystal shapes, and FIG. 2(5) is another schematic representation of the potential distribution for electrons;

FIGS. 3A, 3B, and 3C are schematic representations of a process explaining an example of a manufacturing method of the image display devices according to the present invention, where FIGS. 3A, 3B, and 3C represent sequential steps, respectively;

FIGS. 4D, 4E, and 4F are other schematic representations of the process explaining the example of the manufacturing method of the image display devices according to the present invention, where FIGS. 4D, 4E, and 4F represent sequential steps continuing from those in FIGS. 3A, 3B, and 3C, respectively;

FIG. 5G is still another schematic representation of the process explaining the example of the manufacturing method of the image display devices according to the present invention, where FIG. 5G represents a step continuing from those in FIGS. 4D, 4E, and 4F;

FIGS. 6H and 6I are still other schematic representations of the process explaining the example of the manufacturing method of the image display devices according to the present invention, where FIG. 6H and FIG. 6I represent sequential steps continuing from that in FIG. 5G;

FIGS. 7J and 7K are still other schematic representations of the process explaining the example of the manufacturing method of the image display devices according to the present invention, where FIG. 7J and FIG. 7K represent sequential steps continuing from those in FIGS. 6H and 6I;

FIGS. 8L and 8M are still other schematic representations of the process explaining the example of the manufacturing method of the image display devices according to the present invention, where FIG. 8L and FIG. 8M represent sequential steps continuing from those in FIG. 7J and FIG. 7K;

FIG. 9N is still another schematic representation of the process explaining the example of the manufacturing method of the image display devices according to the present invention, where FIG. 9N represents a step continuing from those in FIG. 8L and FIG. 8M;

FIGS. 10(1) and 10(2) are graphs representing transfer characteristics of p-channel thin film transistors that show an effect of the present invention, where FIG. 10(1) represents transfer characteristics of a p-channel thin film transistor having crystals approximately in a band shape and FIG. 10(2) represents transfer characteristics of a p-channel thin film transistor having ELA crystals;

FIGS. 11 (1) and 11(2) are graphs representing transfer characteristics of n-channel thin film transistors that show another effect of the present invention, where FIG. 11(1) represents transfer characteristics of an n-channel thin film transistor having crystals approximately in a band shape and FIG. 11(2) represents transfer characteristics of an n-channel thin film transistor having conventional ELA crystals;

FIG. 12 is a graph representing an improvement in resistance to hot carriers that is still another effect of the present invention;

FIG. 13 is a circuit diagram of a CMOS inverter circuit making use of the thin film transistor according to the present invention;

FIG. 14 is a diagram showing a layout example of the CMOS inverter circuit making use of the thin film transistor according to the present invention;

FIG. 15 is a perspective development view explaining a structure of a liquid crystal display as a first example of the image display devices of the present invention;

FIG. 16 is a cross sectional view sectioned along the direction of a line Z-Z in FIG. 15;

FIG. 17 is a perspective development view explaining a structural example of an organic EL display as a second example of the image display devices of the present invention; and

FIG. 18 is a plan view of the organic EL display in which structural components shown in FIG. 17 are integrated.

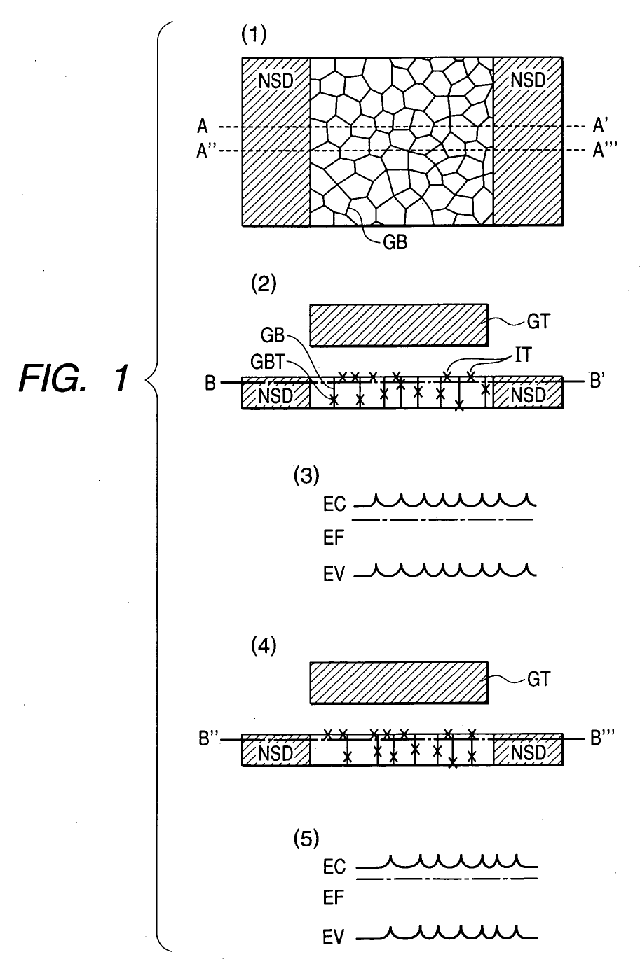

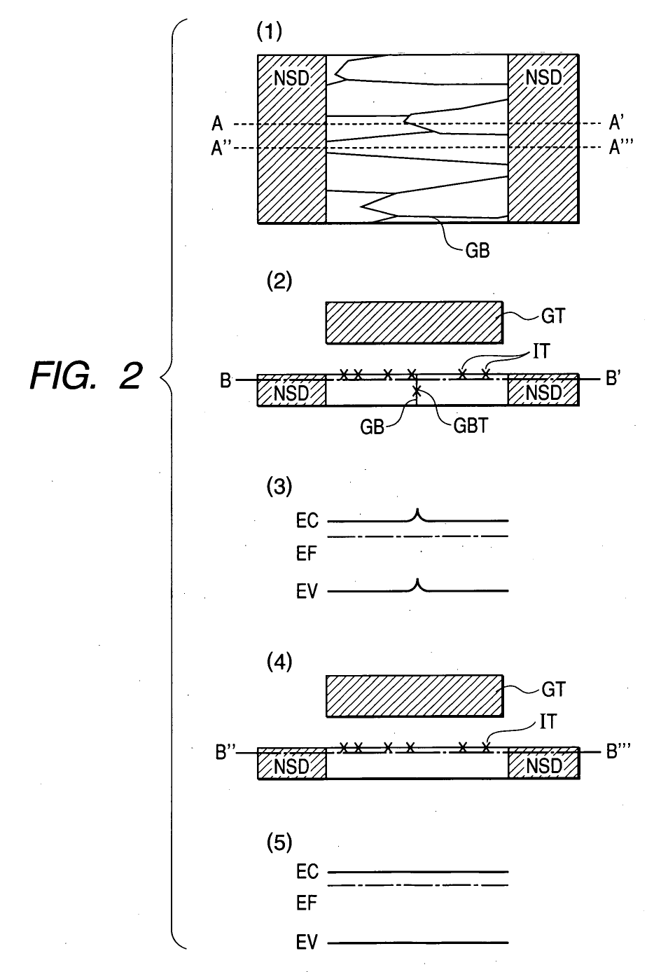

### DETAILED DESCRIPTION OF THE INVENTION

Hereinafter, representative embodiments of the present invention are explained.

(1) In order to achieve the object of the present invention, an image display device according to a first aspect of the invention is characterized in that the image display device is provided with a substrate having a pixel area with numerous pixels formed in a matrix and a peripheral circuit area formed around the periphery of the pixel area and having circuits formed to drive the pixels; a semiconductor device formed at least in the peripheral circuit area includes a thin film transistor having a crystalline thin film approximately in a band shape, in which crystal grains are allowed to grow and crystallize in the direction nearly parallel to the direction of current conduction and which serves as a semiconductor thin film constituting a channel, and a gate oxide film formed on the crystalline thin film approximately in a band shape; and fluorine is introduced into at least the interface between the gate oxide film and the semiconductor thin film constituting the channel.

It is desirable that the concentration of fluorine at the interface between the gate oxide film and the semiconductor thin film is higher than that in the inside of the semiconductor thin film.

It is desirable that the atomic concentration of fluorine at the interface between the gate oxide film and the semiconductor thin film of the thin film transistor is equal to or higher than 0.05% relative to that of silicon. More preferably it is approximately from 0.5 to 3.0%.

(2)-In order to achieve the object of the present invention, the image display devices according to a second aspect of the invention is characterized in that part or the whole of the driving circuits are formed on the same substrate as for the pixel portions; the driving circuit on the substrate is provided with a thin film transistor having a crystalline semiconductor thin film approximately in a band shape in which crystal grains are allowed to grow and crystallize in the direction nearly parallel to the direction of current conduction as well as a concentration distribution of fluorine higher at the interface between the gate oxide film and the semiconductor thin film than in the inside of the semiconductor thin film; and a pixel portion other than the above driving circuit on the substrate is provided with a thin film transistor making use of a granular crystalline semiconductor thin film.

The image display device according to the above (2) is characterized in that part or the whole of the driving circuits are formed on the same substrate as for the pixel portions; the driving circuits on the substrate are provided with two kinds of thin film transistors consisting of the thin film transistor having a crystalline semiconductor thin film approximately in a band shape in which crystal grains are allowed to grow and crystallize in the direction nearly parallel to the direction of current conduction as well as the concentration distribution of fluorine higher at the interface between the gate oxide film and the semiconductor thin film than in the inside of the semiconductor thin film and the thin film transistor making use of the granular crystalline semiconductor thin film; and the pixel portions other than the above driving circuit on the substrate are provided with the thin film transistor making use of the granular crystalline semiconductor thin film.

The image display device according to the above (1) is characterized by a liquid crystal display or an organic EL display.

Further, the image display device according to the above (1) is characterized in that the power voltage for the driving circuit provided with the thin film transistor in which the semiconductor thin film having the crystal structure approximately in a band shape is utilized as the channel is in the range of 1.0 to 6.0 V.

Still further, the image display device according to the above (1) is characterized in that the concentration of fluorine per unit volume of the gate oxide film constituting the above thin film transistor for the driving circuit in the region of 10 nm thickness from the interface with the semiconductor thin film is higher than that in the inside of the above semiconductor thin film, and this semiconductor thin film is composed of a crystalline thin film approximately in a band shape in which crystal grains are allowed to grow and crystallize in the direction nearly parallel to the direction of current conduction.

Still further, the image display device according to the above (1) is characterized in that not only is the interface level density at the interface between the gate oxide film and the semiconductor thin film that constitute the thin film transistor for the above driving circuit equal to or lower than 7×10¹¹/cm²/eV at the mid of the band-gap but also the above semiconductor thin film is composed of the crystalline thin film approximately in a band shape in which crystal grains are allowed to grow and crystallize in the direction nearly parallel to the direction of current conduction.

(3) In order to achieve the object of the present invention, according to a third aspect of the invention, a method for manufacturing the image display device having the substrate with the thin film transistor formed thereon as the driving circuit to drive pixels around the periphery of a pixel area is characterized in that the process to manufacture the thin film transistor includes the steps of forming a first semiconductor thin film made of an amorphous or polycrystalline material on an insulating substrate; allowing a second semiconductor thin film to grow as crystals approximately in a band shape by irradiating a continuous wave laser to an arbitrary region of the first semiconductor thin film, scanning the continuous wave laser relatively to the above substrate, and crystallizing in the direction nearly parallel to the scanning direction; forming the gate oxide film on the second semiconductor thin film made of crystals approximately in a band shape; and introducing fluorine into at least the vicinity of the interface between the gate oxide film and the second semiconductor thin film via thermal diffusion by implanting an ion of a molecule containing fluorine ion or fluorine atom into the depth proximal to the surface of the gate oxide film using an ion implantation apparatus.

### EMBODIMENT

Hereinafter, embodiments of the present invention applied to a liquid crystal display and an organic EL display are described. Here, a glass substrate is used for an active matrix substrate. However, it is needless to say that the present invention is also applicable to an image display device that uses an insulating substrate such as plastic substrate.

### First Embodiment

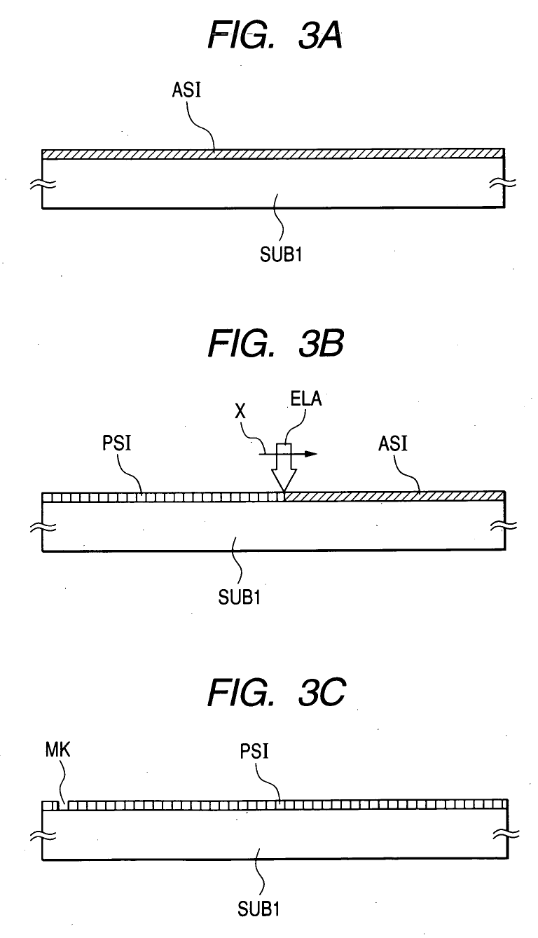

The present embodiment shows a manufacturing example in which a thin film transistor to drive pixels is formed on an active matrix substrate. The manufacturing method explained here exemplifies the production of a CMOS thin film transistor where an n-type thin film transistor is formed by self-aligned GOLDD (gate overlapped lightly doped drain) and a p-type thin film transistor is formed by counter doping. Hereinafter, a sequential manufacturing process is explained step by step according to FIGS. 3A to 9N.

FIG. 3A: First, a glass substrate SUB1 having a thickness of approximately from 0.3 mm to 1.0 mm that is preferably little deformed and contracted by thermal treatment at 400 degrees C. to 600 degrees C. is prepared as an insulating substrate serving as an active matrix substrate.

Preferably, a SiN film having a thickness of about 140 nm and a SiO film having a thickness of about 100 nm that function as thermal and chemical barrier films are successively and uniformly deposited by a chemical vapor deposition (CVD) method over this glass substrate SUB1. An amorphous silicon film ASI is formed on this glass substrate SUB1 by means of CVD and the like.

FIG. 3B: Then, an excimer laser beam ELA is scanned in the x direction to melt and crystallize the amorphous silicon film ASI, thereby modifying the whole amorphous silicon film ASI on the glass substrate SUB1 into polycrystalline silicon film, that is, polysilicon film PSI.

In place of the excimer laser beam ELA, alternatives that could be employed include, for example, crystallization by solid pulse laser annealing, Cat-CVD film turned into polysilicon film at the time of silicon film formation, and SiGe film.

FIG. 3C: A positioning mark MK that becomes a target for positioning of irradiation with a laser beam SXL such as pulse modulated laser beam to be described later (Note that explanations here are given by assuming that pulse modulated laser beam is used) or the like is formed by laser annealing.

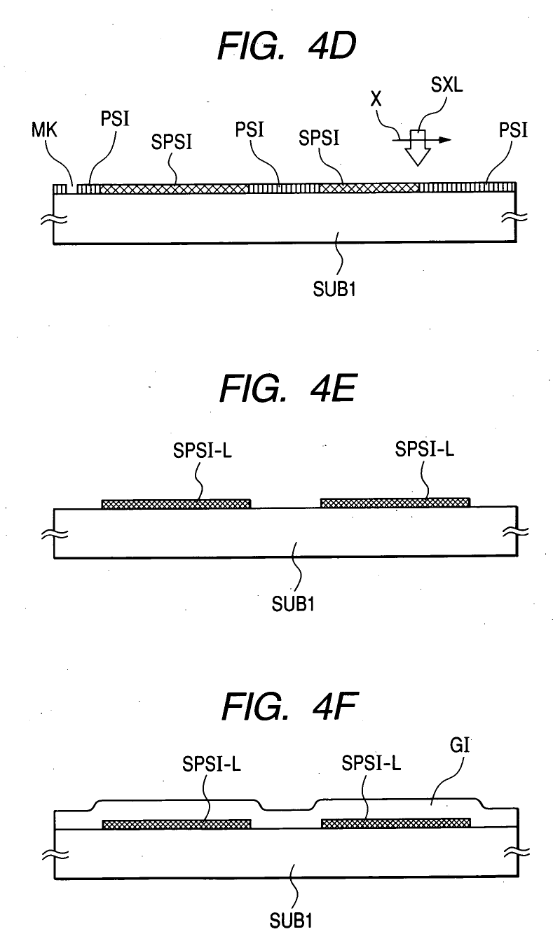

FIG. 4D: With reference to the mark MK, the pulse modulated laser beam SXL is discontinuously irradiated while scanning it in the x direction and selecting predetermined regions. The polysilicon film PSI is modified by this selective irradiation to form crystalline silicon films SPSI (modified region) approximately in a band shape having continuous grain boundaries in the scanning direction. It should be noted that two crystalline silicon films SPSI approximately in a band shape are separately formed in each region for formation of thin film transistors in the figure. However, one crystalline silicon film SPSI approximately in a band shape may be formed without dividing into two, which may be patterned later.

FIG. 4E: The crystalline silicon film SPSI approximately in a band shape is processed with the use of photolithography to form islands SPSI-L for fabricating a thin film transistor.

FIG. 4F: A gate oxide film GI is formed by covering over the islands SPSI-L of the crystalline silicon film SPSI approximately in a band shape.

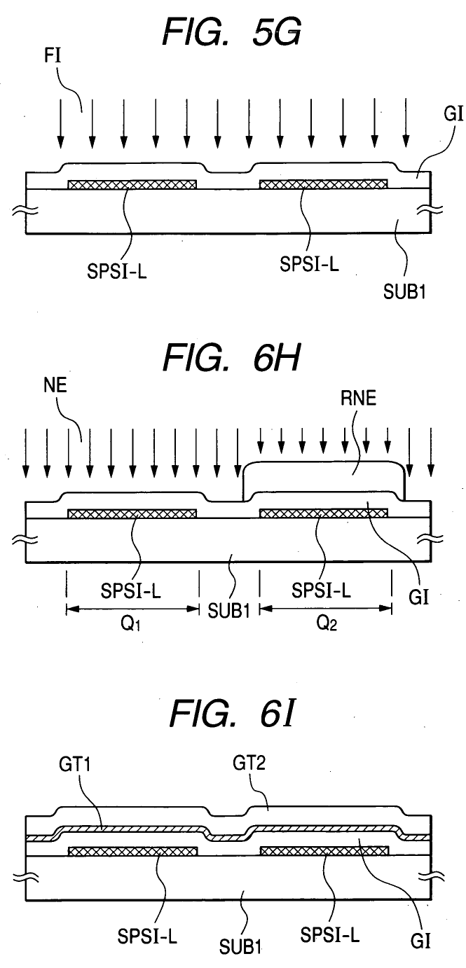

FIG. 5G: At this step, implantation of fluorine ion is carried out. F+ ion is implanted, for example, at an implantation energy of 15 keV and at an implantation dose of 1×10¹⁵ F⁺/cm². In order to prevent damage due to the implantation, the depth of the implantation is set to the vicinity of the surface of the gate oxide film GI so as to intentionally avoid the interface between the gate oxide film and the semiconductor thin film SPSI-L.

FIG. 6H: Implantation NE to control a threshold voltage is carried out in the region where an n-type thin film transistor Q1 is formed. At this time, the region where a p-type thin film transistor Q2 is formed is covered with a photoresist RNE.

Next, Implantation PE to control a threshold voltage is carried out in the region where the p-type thin film transistor Q2 is formed. At this time, the photoresist RNE that covers the region where the p-type thin film transistor Q2 is formed is removed, and instead the region where the n-type thin film transistor Q1 is formed is covered with a photoresist RPE not shown in a manner similar to that when the n-type thin film transistor Q1 is formed, and then implantation PE is carried out.

FIG. 6I: Then, two layers of metal gate films GT1 and GT2 that serve as gate electrodes for the thin film transistor are formed thereon by means of sputtering or CVD.

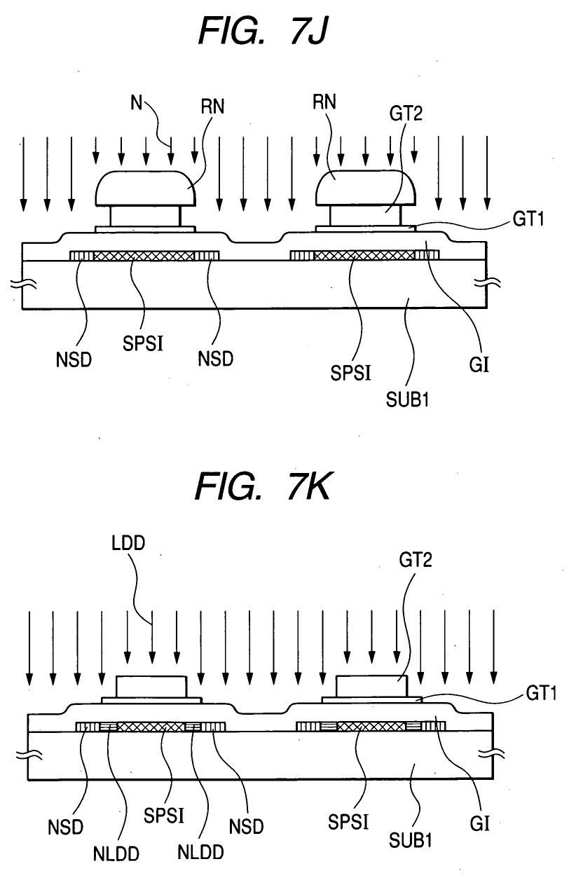

FIG. 7J: The region where the metal gate films GT1 and GT2 are formed is covered with a photoresist RN, and the metal gate films GT1 and GT2 are patterned by photolithography. At this time, the upper layer of the metal gate film GT2 is subjected to side-etching by a predetermined depth to set back from the lower layer of the metal gate film GT1 in order to form a light doped drain region (LDD region). In this state, an n-type impurity N is implanted with the photoresist RN as a mask to form the source and drain regions NSD of the n-type thin film transistor Q1.

FIG. 7K: The photoresist RN is peeled off, and implantation LDD is carried out with the metal gate film GT2 as a mask to form the LDD regions NLDD of the n-type thin film transistor.

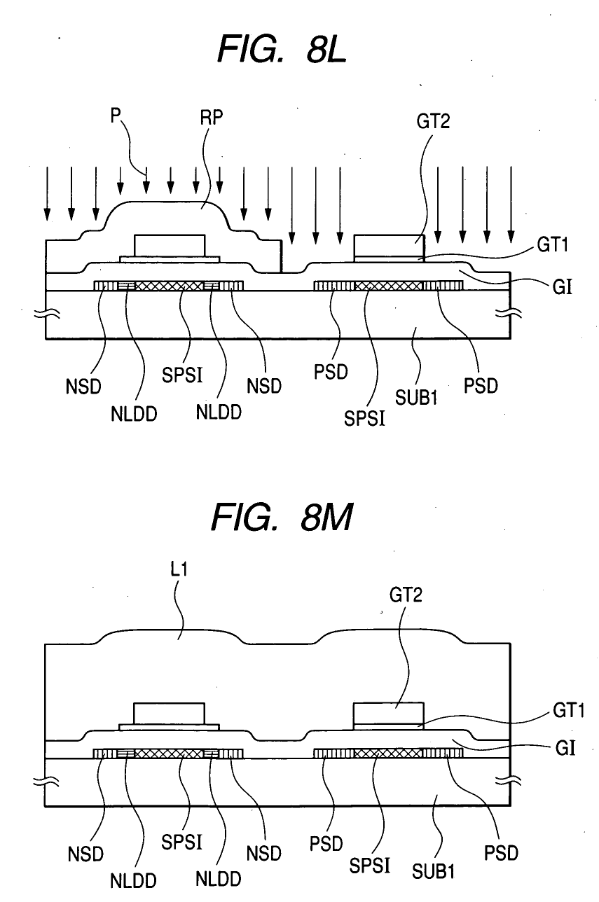

FIG. 8L: The region where the n-type thin film transistor Q1 is formed is covered with a photoresist RP, and a p-type impurity P is implanted into the regions where the source and drain of the p-type thin film transistor Q2 is formed, thereby forming the source and drain regions PSD of the p-type thin film transistor.

FIG. 8M: The photoresist RP is peeled off, and the implanted impurities are activated by thermal treatment. At the same time, the fluorine ion-implanted into the vicinity of the surface of the gate oxide film GI is introduced into the interface between the gate oxide film GI and the crystalline silicon film SPSI approximately in a band shape by thermal diffusion. The thermal treatment is performed in nitrogen atmosphere for 5 hours at 600 degrees C. Then, an interlayer dielectric film L1 is formed by means of CVD and the like. In this way, the atomic concentration of fluorine introduced into the interface between the gate oxide film and the semiconductor thin film is about 0.5% relative to that of silicon.

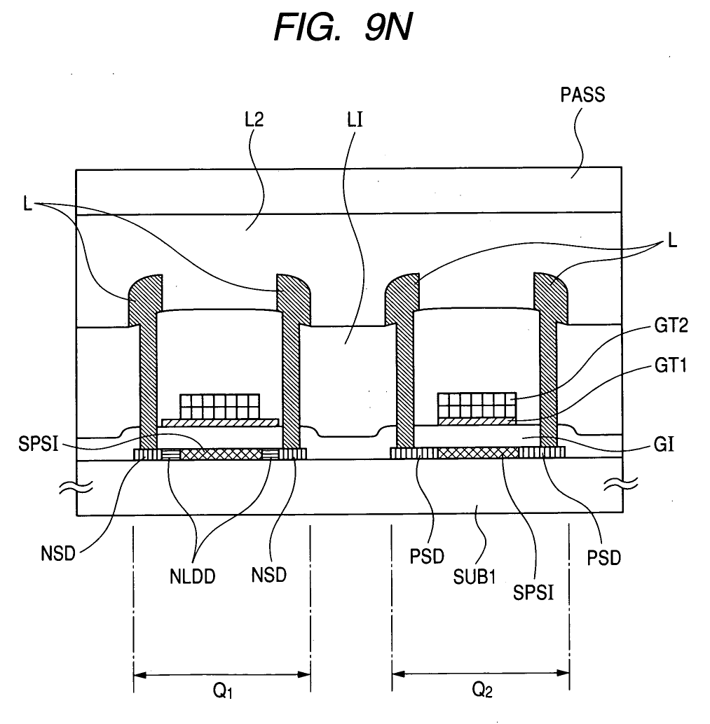

FIG. 9N: By means of photolithography, contact holes are formed on the inter layer dielectric film L1 and the gate oxide film GI, and metal layers for wiring are connected to each of the source and drain NSD and PSD of the n-type thin film transistor Q1 and the p-type thin film transistor Q2, respectively, via the contact holes to form wiring L. On top of this is formed an inter layer dielectric film L2 and further a protective dielectric film PASS. In this example, the inter layer dielectric film L1 is a SiO₂ film, the inter layer dielectric film L2 is a SiN film, wiring metal layers L are made of aluminum, and the protective dielectric film PASS is an organic dielectric film.

According to the foregoing process, a CMOS thin film transistor in which fluorine is introduced into the interface between the crystalline silicon film SPSI approximately in a band shape and the gate oxide film GI is formed.

Incidentally, deterioration of n-type thin film transistors is generally serious. This deterioration is reduced by forming a LDD region between the channel and each of the source and drain regions. GOLDD has a structure in which the gate electrode covers the LDD region. In this case, performance degradation observed with LDD is reduced.

Deterioration of p-type thin film transistors is not so serious as that of n-type thin film transistors, and therefore the LDD region and GOLDD are not generally employed. Although the GOLDD structure is used in this embodiment, the effect of the present invention can also be obtained even when a single drain structure or LDD structure is used. The characteristics of the transistor fabricated as above are shown below.

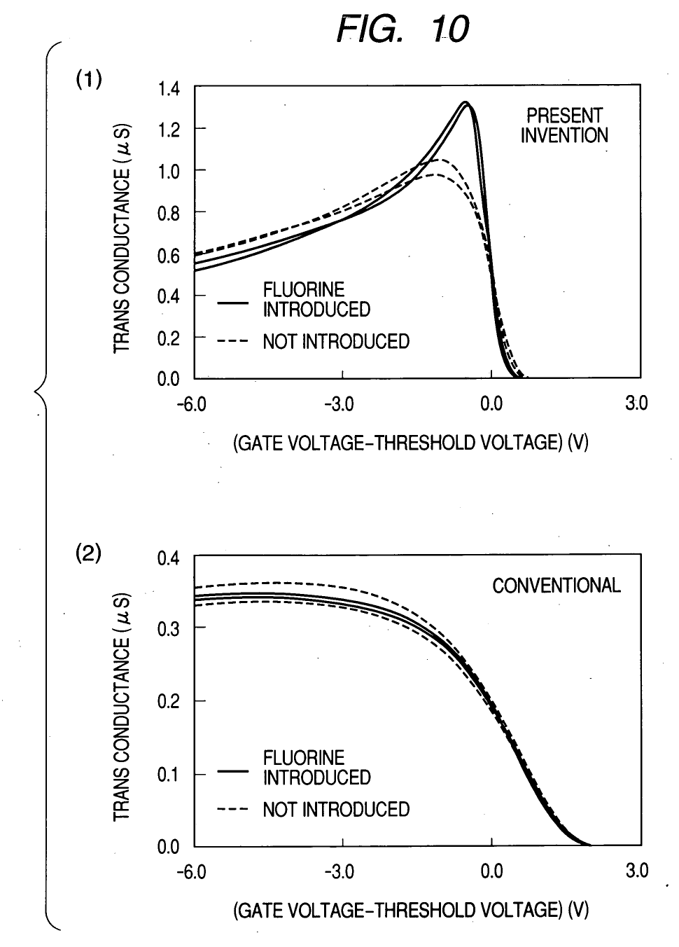

FIGS. 10(1), 10(2), 11(1), and 11(2) show the results of experiments on the thin film transistors according to the present invention. In FIGS. 10(1), 10(2), the present invention is applied to a p-channel thin film transistor, and dependence of its transconductance on the gate voltage is measured. The dimension of the thin film transistor is 4 μm in channel length and 4 μm in channel width, and the drain voltage at the time of measurement of transconductance is 0.1 V.

FIG. 10(1) represents an example according to the present invention in which fluorine is introduced into the interface between the gate oxide film and the channel of the p-type thin film transistor having crystals approximately in a band shape, which is grown and crystallized in the direction nearly parallel to that of carrier conduction, for the channel. FIG. 10(2) represents a comparative example in which fluorine is introduced into the interface between the gate oxide film and the channel of the p-type thin film transistor having ELA crystals for the channel. In both figures, the solid lines indicate the results obtained from the samples introduced with fluorine, and the dotted lines indicate the results obtained from samples not introduced with fluorine.

In FIG. 10(1), the maximum value of the transconductance becomes larger by introducing fluorine, steepness in the range of gate voltage from an OFF state to the maximum value of the transconductance increases, and thus the effect of introducing fluorine into the gate oxide film and channel interface is obvious. Improvement in the characteristics is remarkable at low voltages where the gate voltage is within 1 V from the threshold voltage. Accordingly, it becomes possible to operate at a voltage equal to or lower than 6V and to drive pixels stably at a power voltage of 1 to 6 V for the driving circuit.

Despite the fact that fluorine is introduced, its effect is not seen in FIG. 10 (2); hence effectiveness of the present invention can be verified. In other words, in the present invention, it can be understood that the fact that the semiconductor thin film constituting the channel is made of crystals approximately in a band shape that is grown and crystallized in the direction nearly parallel to that of carrier conduction and that fluorine is introduced into the interface between the gate oxide film and the channel consisting of this semiconductor thin film constitutes important features.

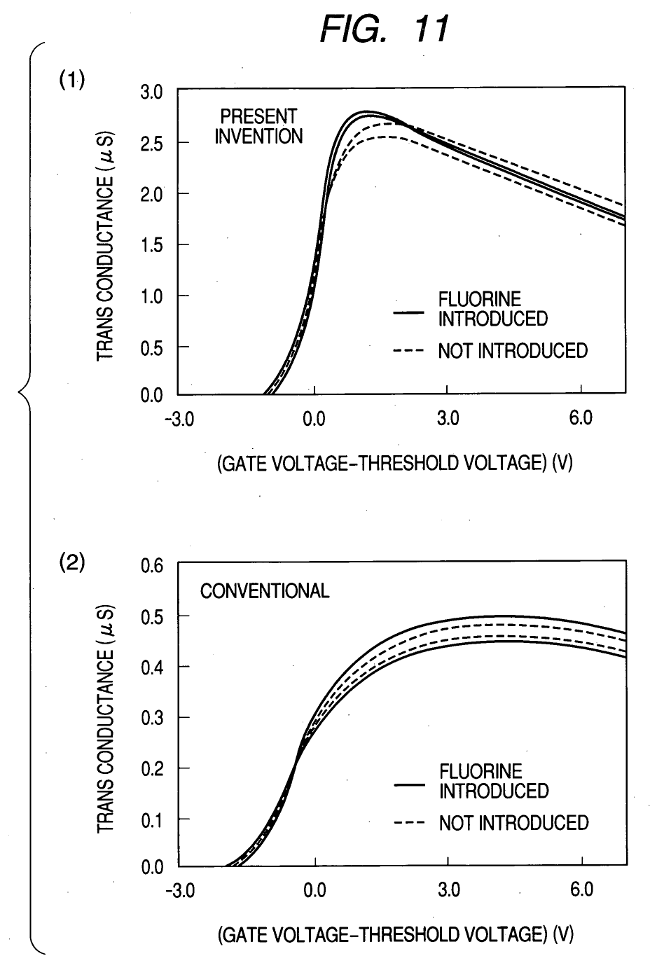

In FIGS. 11(1) and 11(2), the present invention is applied to an n-channel thin film transistor, and dependence of its transconductance on the gate voltage is measured. In FIG. 11(1) that represents an example in which crystals approximately in a band shape and interface termination by introducing fluorine are combined in a similar manner as in the above p-channel thin film transistor, an increase of the maximum transconductance by introducing fluorine and an increase of steepness in the range of gate voltage from an OFF state to the maximum value of the transconductance can be observed.

These can not be observed, however, in FIG. 11(2) that represents an example in which conventional ELA crystals and interface termination by introducing fluorine are combined. Thus, effectiveness of the present invention are also be verified in the n-channel thin film transistor. As is apparent from the comparison of FIG. 10(1) with FIG. 11(1), the effect of introducing fluorine is more significant in the p-channel thin film transistor than in the n-channel thin film transistor.

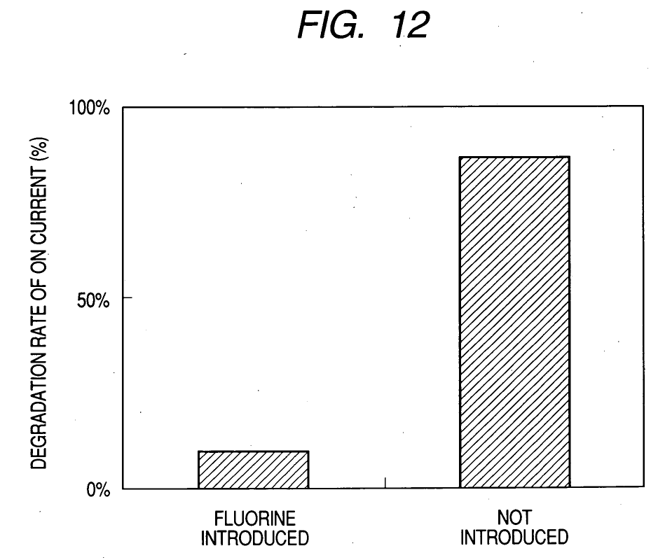

FIG. 12 shows the resistance of the n-channel thin film transistor having crystals approximately in a band shape that are in the same structure as in FIG. 11(1). The thin film transistor is maintained for 100 sec under a condition in which hot carriers are generated (drain voltage=9 V, gate voltage=threshold voltage+1 V), and then the rate of deterioration of ON current is measured. The ON current is defined as the drain current value at the drain voltage of 0.1 V and the gate voltage of 6 V. When fluorine is introduced, the rate of deterioration of ON current by hot carriers is suppressed up to one tenth. As described in the foregoing, the present invention makes it possible to realize high reliability and high performances of the thin film transistor at the same time.

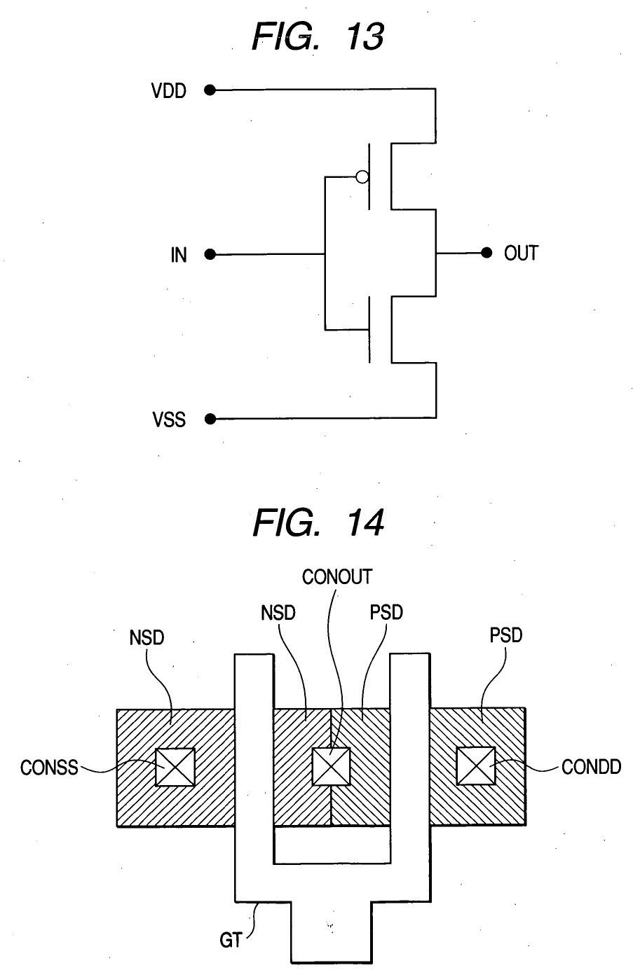

FIG. 13 is a circuit example of CMOS inverter making use of the thin film transistor fabricated as above. In the figure, VDD, VSS, IN, and OUT represent power voltage, standard voltage, input terminal, and output terminal, respectively. FIG. 14 is a layout example of the circuit of the CMOS inverter shown in FIG. 13. In the figure, PSD, NSD, GT, CONDD, and CONSS represent the source and drain of the p-channel thin film transistor, the source and drain of the n-channel thin film transistor, metal wiring (gate electrode), contact hole for the power voltage, and contact hole for the standard voltage, respectively.

### Second Embodiment

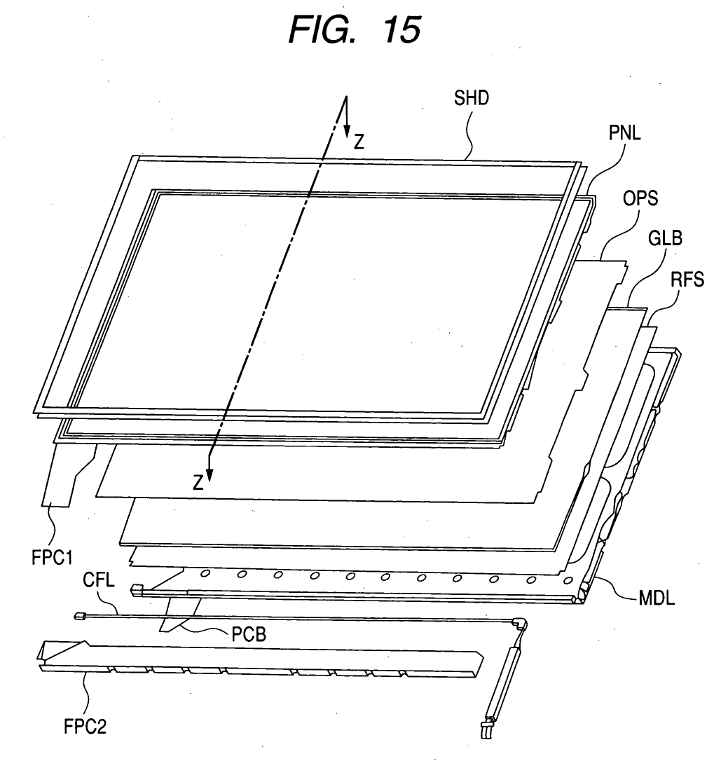

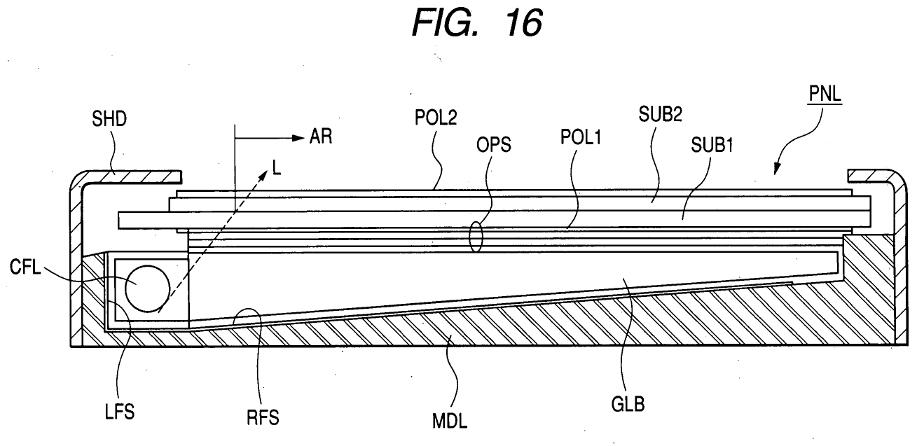

This embodiment represents an application of the present invention to a liquid crystal display. Hereinafter, the embodiment is explained according to FIGS. 15 and 16. FIG. 15 is a perspective development view explaining a structure of the liquid crystal display as a first example of the image display devices of the present invention. Further, FIG. 16 is a cross sectional view sectioned along the direction of the line Z-Z in FIG. 15. This liquid crystal display is manufactured by using the active matrix substrate SUB1 described in the first embodiment.

In FIGS. 15 and 16, a symbol PNL is a liquid crystal cell in which a liquid crystal is sealed in a space sandwiched by the active matrix substrate SUB1 and an opposing substrate SUB2, and its surface and back surface are laminated with polarizing plates POL1 and POL2, respectively. A symbol OPS represents optical compensation materials composed of diffusion sheet and prism sheet, GLB represents an optical guide plate, CFL represents a cold cathode fluorescent lamp, RFS represents a reflection sheet, LFS represents a lamp reflection sheet, SHD represents a shield frame, and MDL represents a molded case.

On the active matrix substrate SUB1 having any one of the structures in the embodiment described above, a liquid crystal alignment layer is formed by a known process, and an alignment controlling force is provided thereto by means of rubbing and the like. After forming a sealing member around the periphery of a pixel area AR, the opposing substrate SUB2 on which an alignment layer is similarly formed is placed opposite with a predetermined gap, a liquid crystal is sealed in this gap, and an opening of the sealing member is closed with a sealant.

The polarizing plates POL1 and POL2 are laminated on the surface and the back surface of the liquid crystal cell PNL constructed in this way as shown in FIG. 16, and a backlight composed of parts such as the optical guide plate GLB and the cold cathode fluorescent lamp CFL, and the like are mounted via the optical compensation materials OPS, thereby manufacturing the liquid crystal display.

Data and timing signals are supplied to the driving circuits arranged around the liquid crystal cell via flexible print-circuit boards FPC1 and FPC2 as shown in FIG. 15. Between the external signal source and each of the print-circuit boards FPC1 and FPC2, a timing controller represented by a symbol PCB, which converts display signals input from an external signal source into a signal form displayed on the liquid crystal display and the like are mounted.

The liquid crystal display of the present embodiment that makes use of the active matrix substrate SUB1 is excellent in current driving capability by arranging the excellent thin film transistor circuit described above for its pixel circuits, and therefore it is suitable for a high speed operation. A further feature is that the liquid crystal display can be supplied at a low cost by reducing the number of LSI.

### Third Embodiment

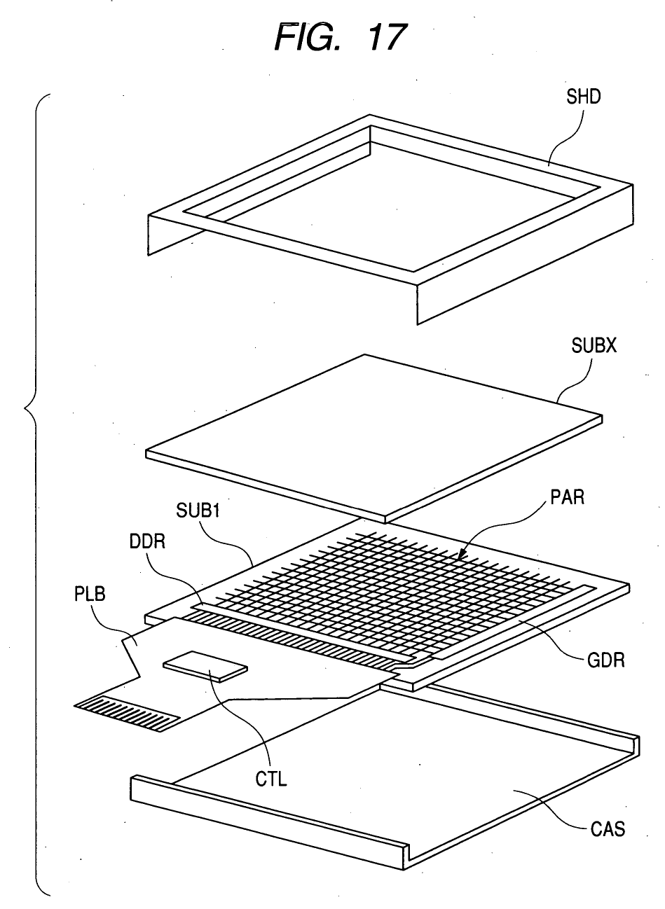

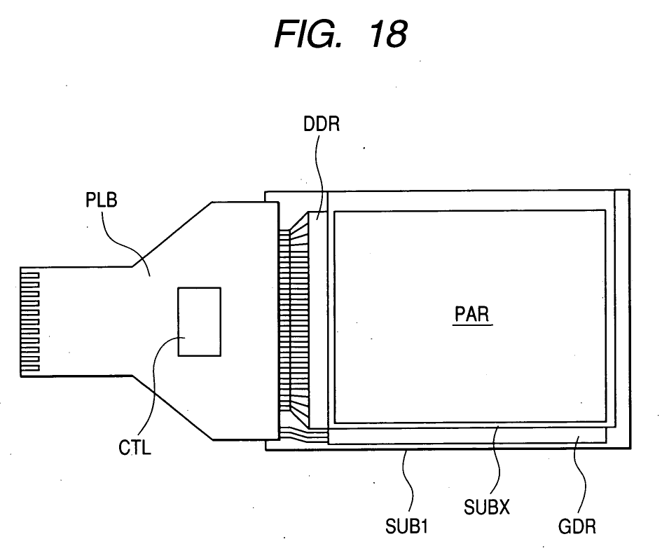

This embodiment represents an application of the present invention to an organic EL display. Hereinafter, the embodiment is explained according to FIGS. 17 and 18. FIG. 17 is a perspective development view explaining a structural example of the organic EL display as a second example of the image display devices of the present invention. Further, FIG. 18 is a plan view of the organic EL display in which the structural components shown in FIG. 17 are integrated.

The organic EL device is formed on pixel electrodes provided on any one of the active matrix substrates SUB1 in each of the embodiments described above. The organic EL device is composed of a laminate in which a hole transport layer, emissive layer, electron transport layer, metal cathode, and the like are deposited in turn on the surface of the pixel electrodes.

Around the periphery of a pixel area PAR formed with such a laminate on the active matrix substrate SUB1, a sealing member is placed, followed by sealing with a sealing substrate SUBX or a sealing canister. A protective film may also be used in place of these.

In this organic EL display, signals for display from an external signal source are supplied to its peripheral circuit areas DDR and GDR by a print-circuit board PLB. An interface circuit chip CTL is mounted on this print-circuit board. Unifying these with a shield frame SHD, i.e. an upper case and a lower case CAS makes up the organic EL display.

Since the organic EL device makes use of a current-driven light emitting system in the active matrix driving for the organic EL display, employment of a high-performance pixel circuit is essential for provision of images with high quality, and therefore, it is desired to use a pixel circuit for CMOS-type thin film transistor. Further, the thin film transistor circuit formed in the peripheral circuit area is also essential for high-speed and high definition. The active matrix substrate SUB1 of the present embodiment has a high performance to meet such requirements. The organic EL display with the use of the active matrix substrate SUB1 fabricated according to the manufacturing method in the preceding first embodiment is one of the display devices that make the best possible use of the feature of the present embodiment.

1. An image display device provided with a substrate having a pixel area with numerous pixels formed in a matrix and a peripheral circuit area formed around the periphery of the pixel area and having circuits formed to drive the pixels, comprising:
a semiconductor device formed in the peripheral circuit area including at least a thin film transistor having a crystalline thin film approximately in a band shape, serving as a semiconductor thin film constituting a channel, crystallized so as to allow crystal grains to grow in the direction nearly parallel to the direction of current conduction, and a gate oxide film formed on the crystalline thin film approximately in a band shape, wherein fluorine is introduced into at least the interface between the gate oxide film and the semiconductor thin film constituting the channel.

2. The image display device according to claim 1, wherein the concentration of fluorine at the interface between the gate oxide film and the semiconductor thin film is higher than that in the inside of the semiconductor thin film.

3. The image display device according to claim 1, wherein a main alignment with respect to the surface of the semiconductor thin film constituting the channel is {110}.

4. The image display device according to claim 1, wherein the atomic concentration of fluorine at the interface between the gate oxide film and the semiconductor thin film of the thin film transistor is at least 0.05% relative to that of silicon.

5. (canceled)

6. An image display device comprising:
driving circuits formed partly or wholly on the same substrate as for pixel portions;
thin film transistors provided on the driving circuits on the substrate and having not only a crystalline semiconductor thin film approximately in a band shape crystallized so as to allow crystal grains to grow in the direction nearly parallel to the direction of current conduction but also a concentration distribution of fluorine higher at the interface between a gate oxide film and the semiconductor thin film than that in the inside of the semiconductor thin film; and
thin film transistors making use of a granular crystalline semiconductor thin film each provided on a pixel portion other than the driving circuits on the substrate.

7. The image display device according to claim 6, wherein part or the whole of the driving circuits are formed on the same substrate as for the pixel portions; the driving circuits on the substrate are provided with two kinds of the thin film transistors including the thin film transistor that has not only a crystalline semiconductor thin film approximately in a band shape crystallized so as to allow crystal grains to grow in the direction nearly parallel to the direction of current conduction but also the concentration distribution of fluorine higher at the interface between the gate oxide film and the semiconductor thin film than in the inside of the semiconductor thin film and the thin film transistor that makes use of the granular crystalline semiconductor thin film; and the pixel portions other than the driving circuits on the substrate are provided with the thin film transistor that makes use of the granular crystalline semiconductor thin film.

8. The image display device according to claim 1, wherein the image display device is a liquid crystal display.

9. The image display device according to claim 1, wherein the image display device is an organic EL display.

10. The image display device according to claim 1, wherein a power voltage of the driving circuit provided with the thin film transistor that utilizes the crystalline thin film approximately in a band shape as the channel is in the range of 1.0 to 6.0V.

11. The image display device according to claim 1, wherein not only is the concentration of fluorine per unit volume of the gate oxide film constituting the thin film transistor for the driving circuit in the region of 10 nm thickness from the interface with the semiconductor thin film higher than that in the inside of the semiconductor thin film but also the semiconductor thin film is comprised of the crystalline thin film approximately in a band shape crystallized so as to allow crystal grains to grow in the direction nearly parallel to the direction of current conduction.

12. The image display device according to claim 1, wherein not only is the interface level density at the interface between the gate oxide film and the semiconductor thin film that constitute the thin film transistor for the driving circuit equal to or lower than 7×10¹¹/cm²/eV at the mid of the band-gap but also the semiconductor thin film is made of the crystalline thin film approximately in a band shape crystallized so as to allow crystal grains to grow in the direction nearly parallel to the direction of current conduction.
